(19) United States
(12) Patent Application Publication
(10) Pub. No.: US 2021/0233909 A1
(43) Pub. Date: Jul. 29, 2021

(54) FLEXIBLE GAA NANOSHEET HEIGHT AND CHANNEL MATERIALS

(71) Applicant: QUALCOMM Incorporated, San Diego, CA (US)

(72) Inventors: Junjing BAO, San Diego, CA (US); Ye LU, San Diego, CA (US); Peijie FENG, San Diego, CA (US); Chenjie TANG, San Diego, CA (US); Xiaochun ZHU, San Diego, CA (US)

(21) Appl. No.: 16/751,371

(22) Filed: Jan. 24, 2020

(51) Int. Cl. H01L 27/092; H01L 29/06; H01L 29/423; H01L 29/786; H01L 21/02; H01L 21/306; H01L 21/308; H01L 21/8238; H01L 29/66

(52) U.S. Cl. CPC H01L 27/0922; H01L 29/0673; H01L 29/42392; H01L 29/78651; H01L 29/78684; H01L 29/66742; H01L 21/02603; H01L 21/02532; H01L 21/30604; H01L 21/308; H01L 21/823807; H01L 29/78696

(57) ABSTRACT

Certain aspects of the present disclosure relate to a gate-all-around (GAA) semiconductor device. One example GAA semiconductor device includes a plurality of nanosheet stack structures disposed vertically above a horizontal plane of a substrate, wherein: each nanosheet stack structure of the plurality of nanosheet stack structures comprises one or more nanosheets; the one or more nanosheets of a first nanosheet stack structure of the plurality of nanosheet stack structures comprise a first semiconductor material; and the one or more nanosheets of a second nanosheet stack structure of the plurality of nanosheet stack structures comprise a second semiconductor material different from the first semiconductor material.

### TECHNICAL FIELD

Certain aspects of the present disclosure relate to electronic components and, more particularly, to gate-all-around (GAA) devices with flexible nanosheet height and/or channel materials.

### BACKGROUND

Advances in technology have resulted in smaller and more powerful computing devices. For example, a variety of portable personal computing devices, including wireless telephones such as mobile and smart phones, tablets, and laptop computers, are small, lightweight, and easily carried by users. These devices can communicate voice and data packets over wireless networks. Further, many such devices incorporate additional functionality such as a digital still camera, a digital video camera, a digital recorder, and an audio file player. Additionally, such devices can process executable instructions, including software applications, such as a web browser application, that can be used to access the Internet. As such, these devices can include significant computing capabilities.

Computing devices use a large number of integrated circuits (ICs), such as transistors that may be used for processing logic and transistors used for memory devices. As computing devices continue to decrease in size, the footprint associated with transistors in various ICs tends to increase, relative to the size of the computing devices, unless the size of each transistor can be decreased. Fin field-effect transistor (FinFET) technology has been introduced to overcome this seeming footprint limitation. FinFETs are a type of metal-oxide-semiconductor FET (MOSFET) in which a gate structure is placed on two, three, or four sides of a channel structure, allowing for significantly faster switching times and higher current density than planar MOSFET technology. However, FinFET technology is facing critical scaling issues for sizes less than seven nanometers. Thus, multi-bridge-channel FET (MBCFET) technology, having a vertically stacked nanosheet (NS) and a gate-all-around (GAA) structure, has been developed to replace FinFETs in certain applications.

### SUMMARY

Certain aspects of the present disclosure relate to gate-all-around (GAA) semiconductor devices having multiple nanosheet stack structures, where vertically stacked nanosheets comprise different materials between different stack structures. For certain aspects, the nanosheet stack structures may also have different numbers of nanosheets and/or nanosheets with different channel widths, between different nanosheet stack structures.

Certain aspects of the present disclosure are directed to a GAA semiconductor device. The GAA semiconductor device includes a plurality of nanosheet stack structures disposed vertically above a horizontal plane of a substrate, wherein: each nanosheet stack structure of the plurality of nanosheet stack structures comprises one or more nanosheets, the one or more nanosheets of a first nanosheet stack structure of the plurality of nanosheet stack structures comprise a first semiconductor material, and the one or more nanosheets of a second nanosheet stack structure of the plurality of nanosheet stack structures comprise a second semiconductor material different from the first semiconductor material.

Certain aspects of the present disclosure relate to a method for fabricating a GAA semiconductor device. The method includes forming a plurality of nanosheet stack structures disposed vertically above a horizontal plane of a substrate, wherein: each nanosheet stack structure of the plurality of nanosheet stack structures comprises one or more nanosheets, the one or more nanosheets of a first nanosheet stack structure of the plurality of nanosheet stack structures comprise a first semiconductor material, and the one or more nanosheets of a second nanosheet stack structure of the plurality of nanosheet stack structures comprise a second semiconductor material different from the first semiconductor material.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1A illustrates a three-dimensional view of a conventional fin field-effect transistor (FinFET) semiconductor device.

FIGS. 1B and 1C illustrate a three-dimensional view and a two-dimensional cross-section, respectively, of a conventional gate-all-around (GAA) semiconductor device.

FIG. 2 illustrates an example cross-section of a GAA semiconductor device, according to certain aspects presented herein.

FIGS. 3A-J illustrate example operations for fabricating a GAA semiconductor device, in accordance with certain aspects of the present disclosure.

FIG. 4 is a flow diagram illustrating example operations for fabricating a GAA semiconductor device, in accordance with certain aspects of the present disclosure.

### DETAILED DESCRIPTION

Certain aspects of the present disclosure are directed to a gate-all-around (GAA) semiconductor device. The GAA semiconductor device includes a plurality of nanosheet stack structures disposed vertically above a horizontal plane of a substrate. In some cases, a material used for nanosheets of a first nanosheet stack structure may be different from a material used for nanosheets of a second nanosheet stack structure. Additionally, in some cases, a number of nanosheets in the first nanosheet stack structure may be different from a number of nanosheets in the second nanosheet stack structure.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

Certain terminology may also be used in the following description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

### EXAMPLE CONVENTIONAL GAA SEMICONDUCTOR DEVICE

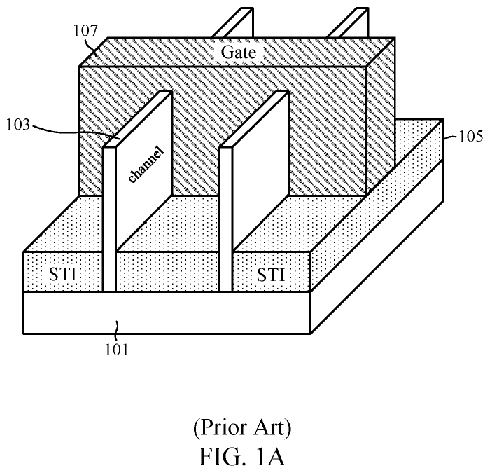

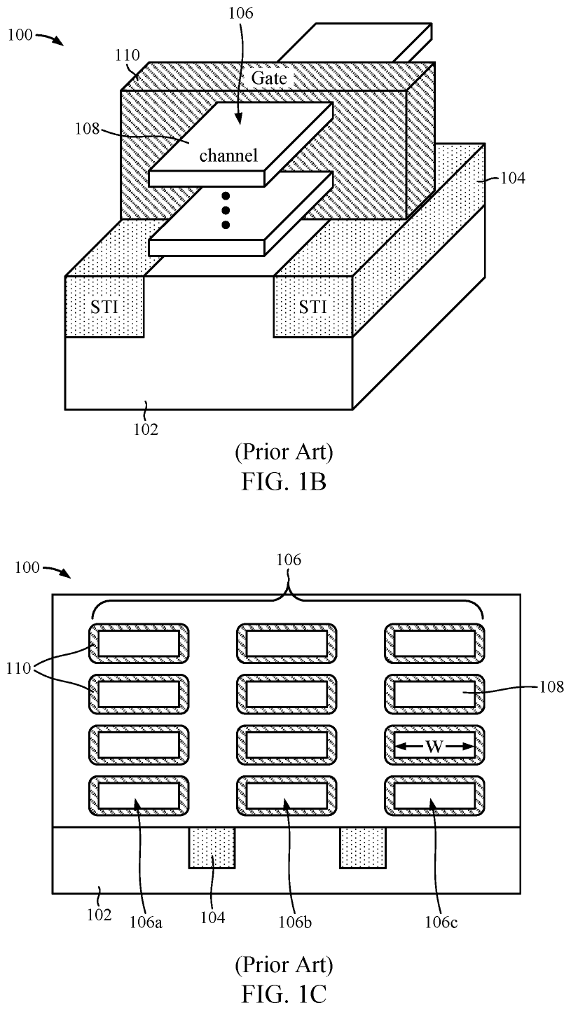

FIG. 1A illustrates a conventional fin field-effect transistor (FinFET). A FinFET is a type of non-planar or three-dimensional transistor that includes a channel structure that rises above the substrate 101 and resembles a fin 103. As illustrated, a shallow trench isolation (STI) structure 105 may be included to provide isolation between each fin 103. The fin 103 provides the semiconductor channel of the transistor between source and drain regions and is surrounded on three sides by a gate region 107, providing more control over the channel as compared to traditional planar transistor designs. However, as transistors continue to scale down, FinFET technology is met with difficulties. For example, as FinFET transistors scale down, an effective width of the channel (e.g., fins) decreases, leading to performance loss. In order to address this performance loss, one solution involves increasing the effective width of the channel. However, increasing the effective width of the channel decreases the transistor density (i.e., the number of transistors that may fit in a given area). In other words, with a larger channel width, less number of cells can fit in the given area.

Thus, in order to increase density and performance, multi-bridge-channel field-effect transistor (MBCFET) technology has been developed to replace FinFETs for sub-3-nm transistor technology in certain applications. MBCFETs include a number of vertically stacked nanosheet structures with a gate-all-around (GAA) structure, providing superior DC performance and better short channel control compared to FinFETs due to the uniform channel thickness.

FIGS. 1B and 1C illustrate a three-dimensional view and a two-dimensional cross-section, respectively, of a conventional GAA semiconductor device 100. More specifically, FIG. 1C illustrates a transverse cross-section through the longitudinal axis of the gate structure of FIG. 1B. As illustrated, the GAA semiconductor device 100 may comprise a substrate layer 102. The substrate layer 102 may be a substrate employed in a semiconductor process, such as a silicon (Si) substrate or any other suitable material (e.g., glass, ceramic, aluminum oxide (Al₂O₃), etc.). FIG. 1C illustrates the cross-section of the substrate layer 102 as a plain rectangle in order to simplify the illustration, and is not intended to be limiting. For example, there may be other shapes and sizes of the substrate layer 102, as well as intervening layers.

Additionally, as illustrated, the GAA semiconductor device 100 may include a plurality of nanosheet stack structures 106, each comprising a plurality of nanosheets 108 stacked vertically above the substrate layer 102. It should be noted that FIG. 1B only illustrates a single nanosheet stack structure 106 (with two or more nanosheet channels) for ease of understanding. However, the GAA semiconductor device 100 may include any number of nanosheet stack structures, such as the three nanosheet stack structures illustrated in FIG. 1C.

In some cases, each nanosheet stack structure of the nanosheet stack structures 106 may serve different functions and correspond to different types of transistor devices. For example, in some cases, nanosheet stack structure 106a may correspond to a pull-up transistor, nanosheet stack structure 106b may correspond to a pass-gate transistor, and nanosheet stack structure 106c may correspond to a pull-down transistor of a static random-access memory (SRAM) cell. Further, as illustrated, a shallow trench isolation (STI) structure 104 may be included within the substrate to provide isolation between different transistor devices.

Each of the nanosheets 108 may be composed of the same semiconductor material, such as silicon (Si), and form a channel between “source” and “drain” terminals through which electrical current may flow. In order to control the electrical current flow through the channel, the nanosheets 108 may be wrapped in a high dielectric constant (high-κ) and metal gate (HKMG) structure 110. The HKMG structure 110 may be known as a “gate” terminal and used to bias the semiconductor material of the channel to control the current flow.

In certain cases, the effective width (labeled “W”) of the nanosheets 108, or “channel,” may be variable, allowing for density and performance of the GAA semiconductor device 100 to be tuned. For example, in some cases, the effective width of the nanosheets 108 may be reduced (e.g., narrow), allowing more MBCFETs to fit in a given area of the GAA semiconductor device 100 (i.e., higher density). In other cases, the effective width of the nanosheets 108 may be increased (e.g., wide), providing the GAA semiconductor device 100 with high performance.

As noted above, MBCFETs, such as the GAA semiconductor device 100, may have superior DC performance and better short channel control compared to FinFETs due to the uniform channel thickness, the larger effective channel width, and the GAA structure (e.g., HKMG structure 110). The wide range of variable nanosheet widths, as opposed to the discrete number of fins for FinFET technology, may also provide greater design flexibility for MBCFETs. However, to achieve a performance increase, the effective channel width of the nanosheets may be increased, leading to similar issues with cell density as FinFET technology. That is, as with FinFET technology, as the effective channel width of the nanosheets in a GAA semiconductor device is increased, a lower number of MBCFETs may fit in the same area.

Thus, aspects of the present disclosure provide techniques for increasing the density of GAA semiconductor devices while at the same time improving performance. For example, in some cases, techniques presented herein involve using different materials for nanosheets of different nanosheet stack structures. For certain aspects, these techniques may also entail varying the nanosheet height (e.g., the number of nanosheets in a stack structure) and/or the nanosheet width between different nanosheet stack structures.

### EXAMPLE GAA SEMICONDUCTOR DEVICE WITH FLEXIBLE NANOSHEET HEIGHT AND CHANNEL MATERIALS

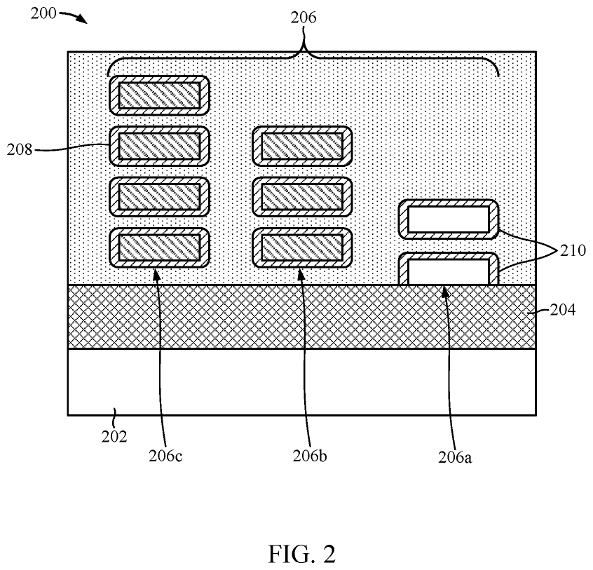

FIG. 2 illustrates an example cross-section of a GAA semiconductor device 200, according to certain aspects presented herein. In some cases, the GAA semiconductor device may be employed in various electrical devices, such as static random access memory (SRAM), to improve performance and/or memory density of such devices.

As illustrated, the GAA semiconductor device 200 may comprise a substrate layer 202. The substrate layer 202 may be a substrate employed in a semiconductor process, such as a silicon (Si) substrate or any other suitable material (e.g., glass, ceramic, aluminum oxide (Al₂O₃), etc.).

Additionally, as illustrated, the GAA semiconductor device 200 may include a plurality of nanosheet stack structures 206 disposed vertically/orthogonally above a horizontal plane of the substrate layer 202. Further, each nanosheet stack structure 206 may include one or more nanosheets 208 that are stacked above the substrate layer 202 of the GAA semiconductor device 200. As noted above, the one or more nanosheets 208 form a channel between “source” and “drain” terminals through which electrical current may flow. Further, as shown, the GAA semiconductor device 200 may include an oxide layer 204 deposited above the substrate layer 202, separating the one or more nanosheets 208 from the substrate layer 202. According to aspects, the oxide layer 204 may be composed of any suitable oxide material, such as silicon dioxide (SiO₂), and may reduce parasitic capacitance between the one or more nanosheets 208 and the substrate layer 202 (e.g., as compared to the GAA semiconductor device 100 that lacks this oxide layer). In some cases, one or more of the nanosheets 208 may be deposited above the oxide layer 204, as illustrated.

As illustrated, the nanosheets 208 of each individual nanosheet stack structure 206 (e.g., 206a, 206b, 206c) may be separated from each other by a high dielectric constant and metal gate (HKMG) structure 210. For example, as illustrated, the one or more nanosheets 208 of nanosheet stack structure 206c may be wrapped and separated from each other by a HKMG structure 210. Further, as noted above, the HKMG structure 210 may serve as a gate terminal or region of the GAA semiconductor device 200, controlling current flow through the channel(s) created by the one or more nanosheets 208.

In some cases, each nanosheet stack structure 206 may serve different functions and correspond to or be part of different types of transistor devices employed in an electric device, such as an SRAM. For example, in some cases, nanosheet stack structure 206a may be part of a pull-up transistor, 206b may be part of a pass-gate transistor, and 206c may be part of a pull-down transistor in an SRAM cell.

According to aspects, to improve performance and/or density of such electric devices (e.g., SRAMs), for example, certain parameters of the nanosheet stack structures 206 corresponding to these different types of transistors may be tuned. For example, in some cases, different semiconductor materials may be used for nanosheets 208 of different nanosheet stack structures 206. Additionally, in some cases, a height (e.g., the number of nanosheets 208) of the nanosheet stack structures 206 may also be varied, such that the stack structures may have different numbers of nanosheets. In some cases, the variation in semiconductor material and/or height of the nanosheet stack structures 206 may be based on the type of transistor device to which the nanosheet stack structures 206 correspond and a current flow associated with such transistor device type.

For example, pull-down transistors in SRAM cells are typically N-type devices, which may be associated with weaker current flow. Therefore, in order to increase current flow and improve performance of the SRAM without increasing a lateral/horizontal area (e.g., with respect to the horizontal plane of the substrate), nanosheet stack structures corresponding to pull-down transistors may include a larger number of nanosheets 208, increasing the effective channel width of these particular nanosheet stack structures without increasing the physical width of the nanosheets in these nanosheet stack structures. For example, as illustrated in FIG. 2, the nanosheet stack structure 206c, which may be part of a pull-down transistor, includes four nanosheets 208, increasing an effective channel width of the nanosheet stack structure 206c without increasing the physical width of the nanosheets 208 and thereby improving the performance associated with this device (e.g., by increasing the current flow). Further, since the physical widths of the nanosheets 208 are not increased to achieve the same increase in performance, a higher density of nanosheet stack structures 206 may fit in a given area.

Pull-up transistors in SRAM cells are typically P-type devices, which may be associated with stronger current flow. Therefore, since pull-up transistors have stronger current flow and thus do not require a large effective channel width, nanosheet stack structures corresponding to, for example, pull-up transistors may include a smaller number of nanosheets 208 (e.g., as compared to nanosheet stack structures corresponding to pull-down transistors). For example, as illustrated in FIG. 2, nanosheet stack structure 206a, which may be part of a pull-up transistor, may include two nanosheets 208.

Pass-gate transistors in SRAM cells are typically N-type devices, which may be associated with weaker current flow. However, because pass-gate transistors may not need stronger current flow and thus may not require a large effective channel width, pass-gate transistors may include a smaller number of nanosheets 208 (e.g., as compared to nanosheet stack structures corresponding to pull-down transistors). For example, as illustrated in FIG. 2, nanosheet stack structure 206b, which may be part of a pass-gate transistor, may include three nanosheets 208.

Accordingly, as illustrated, the GAA semiconductor device 200 may include a first nanosheet stack structure (e.g., 206a) that comprises a first number of nanosheets (e.g., two nanosheets). The GAA semiconductor device 200 may also include a second nanosheet stack structure (e.g., 206c) that comprises a second number of nanosheets (e.g., four nanosheets) different from the first number of nanosheets of the first nanosheet stack structure. Additionally, the GAA semiconductor device 200 may also include a third nanosheet stack structure (e.g., 206b) that comprises a third number of nanosheets (e.g., three nanosheets) different from the first number of nanosheets of the first nanosheet stack structure and different from the second number of nanosheets of the second nanosheet stack structure. In some cases, the first nanosheet stack structure is part of a pull-up transistor, the second nanosheet stack structure is part of a pull-down transistor, and third nanosheet stack structure is part of a pass-gate transistor of an SRAM cell.

Additionally, as noted above, different semiconductor materials may be used for nanosheets 208 of different nanosheet stack structures 206. For example, in some cases as illustrated in FIG. 2, the one or more nanosheets 208 of the first nanosheet stack structure (e.g., 206a) of the plurality of nanosheet stack structures (e.g., 206) may comprise a first semiconductor material. Additionally, in some cases, the one or more nanosheets 208 of the second nanosheet stack structure (e.g., 206c) of the plurality of nanosheet stack structures (e.g., 206) may comprise a second semiconductor material different from the first semiconductor material. Additionally, in some cases, the one or more nanosheets 208 of the third nanosheet stack structure (e.g., 206b) may comprise a third semiconductor material different from the first semiconductor material.

It should be understood that the second semiconductor material and third semiconductor material comprise a different semiconductor material from the first semiconductor material as would be understood by a person of ordinary skill in the art. It should also be understood that the different semiconductor material of the second semiconductor material and third semiconductor material is not intended to cover a semiconductor material that includes primarily the same semiconductor material of the first semiconductor material with impurities, as explained below.

According to aspects, in some cases, the first semiconductor material may comprise one of germanium (Ge) or silicon-germanium (SiGe). Additionally, in some cases, the second semiconductor material and the third semiconductor material may comprise silicon (Si). It should be understood that, while the second semiconductor material and third semiconductor material may comprise silicon, what is meant is that the second semiconductor material and third semiconductor material may comprise primarily silicon and that the second semiconductor material and third semiconductor material do not comprise a semiconductor material such as silicon-germanium (e.g., that also contains silicon) which would be understood by a person of ordinary skill in the art as a different semiconductor material. Further, silicon-germanium refers to a semiconductor material that comprises a specific ratio of both silicon and germanium as would be known and used by persons of ordinary skill in the art and does not include a material such as silicon with minor germanium impurities or vice versa.

According to aspects, in some cases, the one or more nanosheets 208 of the first nanosheet stack structure may be deposited on one or more different horizontal planes and offset from the one or more nanosheets 208 of the second nanosheet stack structure and/or the one or more nanosheets 208 of the third nanosheet stack structure. For example, due to the differing semiconductor materials and GAA semiconductor device 200 fabrication process, as will be explained below, the one or more nanosheets 208 of the nanosheet stack structure 206a may be offset and deposited on one or more different horizontal planes from the one or more nanosheets 208 of the nanosheet stack structure 206b and/or the one or more nanosheets 208 of the nanosheet stack structure 206c.

According to aspects, using different semiconductor materials for the nanosheet stack structures 206 may affect a transistor strength associated with the nanosheet stack structures 206. For example, in some cases, by selecting a semiconductor material such as silicon germanium for the first nanosheet stack structure, corresponding to a pull-up transistor of an SRAM cell, an intrinsic pull-up strength of the pull-up transistor may be increased in addition to a static noise margin (SNM). The SNM may be defined as the minimum DC noise voltage present at each of the SRAM cell storage nodes necessary to change the logic state of the cell. In some cases, by selecting silicon germanium for the first nanosheet stack structure, an intrinsic pull-up strength associated with the first nanosheet stack structure may be increased—in some cases, by greater than 20%—leading to an increase of SNM by one standard deviation at a low operating voltage region (e.g., less than 2.0 V).

According to aspects, in addition to varying semiconductor materials and/or nanosheet stack height, the width of the nanosheets 208 may be tuned independently between different nanosheet stack structures 206 to adjust performance and/or density. For example, in some cases, a width of the one or more nanosheets 208 of the nanosheet stack structure 206a may be different from a width of the one or more nanosheets 208 of the nanosheet stack structure 206b and/or nanosheet stack structure 206c. In some cases, the width of the one or more nanosheets 208 may be dependent on a type of transistor to which the one or more nanosheets 208 correspond. For example, in some cases, to improve performance (e.g., current flow) of an N-type device, such as a pull-down transistor which has weak current flow, the nanosheets corresponding to or part of the pull-down transistor may have a larger width than nanosheets corresponding to or part of a pull-up transistor and/or pass-gate transistor. For other aspects, a combination of nanosheet width and nanosheet height may be adjusted, such that the nanosheets corresponding to or part of a pull-down transistor may have a larger width and a greater number within the stack structure, compared to nanosheets of a nanosheet stack structure for a pull-up transistor and/or a pass-gate transistor.

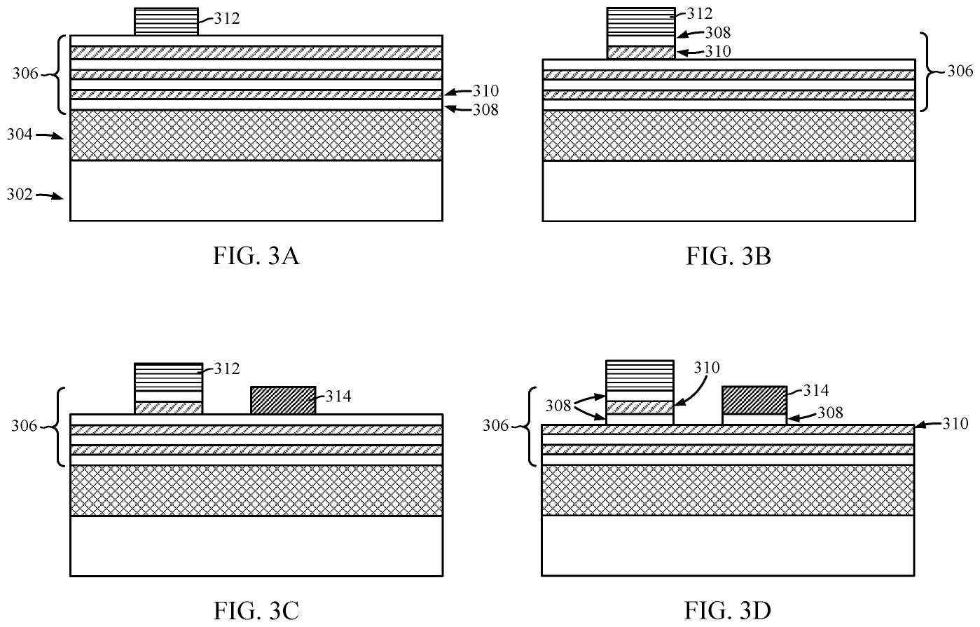

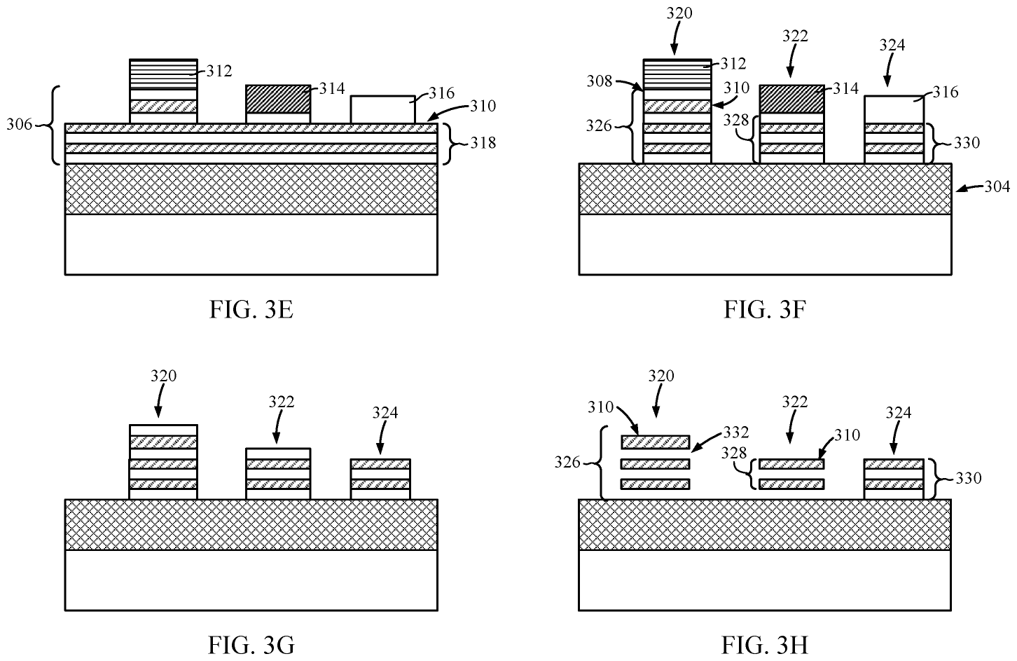

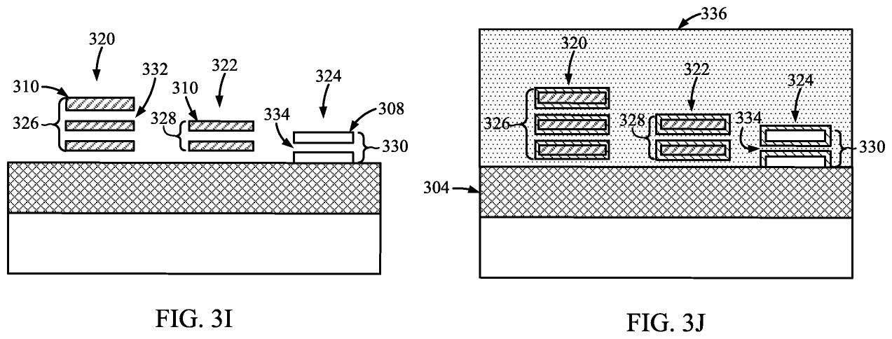

FIGS. 3A-J illustrate example operations for fabricating a GAA semiconductor device, such as the GAA semiconductor device 200, in accordance with certain aspects of the present disclosure. As illustrated in FIG. 3A, the operations may begin by forming a substrate layer 302 and depositing an oxide layer 304 on the substrate layer 302. In some cases, the substrate layer 302 may comprise any suitable semiconductor material, such as silicon. Additionally, the oxide layer 304 may comprise any suitable oxide material, such as silicon dioxide. An epitaxial structure 306 may then be epitaxially grown above the oxide layer 304. As illustrated, the epitaxial structure 306 may comprise a plurality of alternating layers 308 and 310, which will later become the one or more nanosheets of the GAA semiconductor device 200. In some cases, the layers 308 may comprise a semiconductor material, such as germanium (Ge) or silicon germanium (SiGe). Additionally, in some cases, the layers 310 may comprise a semiconductor material, such as silicon (Si).

According to aspects, as illustrated in FIG. 3A, a first photo-resist mask 312 may be deposited on the epitaxial structure 306. The first photo-resist mask 312 may be deposited on a location of the epitaxial structure 306 that corresponds (or will correspond) to a first transistor device/nanosheet stack structure, such as a pull-down transistor device.

As illustrated in FIG. 3B, a single layer 308 (e.g., Ge or SiGe) and a single layer 310 (e.g., Si) may be removed (e.g., etched) from unprotected areas of the top of the remaining epitaxial structure 306, leaving the layers 308 and 310 underneath the first photo-resist mask 312 intact.

Thereafter, as illustrated in FIG. 3C, the first photo-resist mask 312 may be hardened, and a second photo-resist mask 314 may be deposited above (e.g., on top of) the epitaxial structure 306 adjacent to the first photo-resist mask 312. According to aspects, the second photo-resist mask 314 may be deposited on a location of the epitaxial structure 306 that corresponds (or will correspond) to a second transistor device/nanosheet stack structure, such as a pass-gate transistor device.

Thereafter, as illustrated in FIG. 3D, a single layer 308 (e.g., Ge or SiGe) may be removed (e.g., etched) from unprotected areas of the top of the remaining epitaxial structure 306, leaving the layers 308 and 310 underneath the first photo-resist mask 312 and second photo-resist mask 314 intact. As illustrated, after removing the single layer 308 from the top of the epitaxial structure 306, the layer 310 (e.g., Si) is exposed.

Thereafter, as illustrated in FIG. 3E, the second photo-resist mask 314 may be hardened and a third photo-resist mask 316 may be deposited above (e.g., on top of) the exposed layer 310 of the epitaxial structure 306 adjacent to the second photo-resist mask 314. According to aspects, the third photo-resist mask 316 may be deposited on a location of the epitaxial structure 306 that corresponds (or will correspond) to a third transistor device/nanosheet stack structure, such as a pull-up transistor device.

Thereafter, as illustrated in FIG. 3F, remaining layers 318 (e.g., as illustrated in FIG. 3E) may be removed from unprotected areas of the epitaxial structure 306 down to the oxide layer 304, leaving three nanosheet stack structures 320, 322, and 324 each comprising alternating remaining portions of layers 308 and 310, known as nanosheets. For example, as illustrated, the nanosheet stack structure 320 may include nanosheets 326 comprising four nanosheets corresponding to layer 308 (e.g., Ge or SiGe) and three nanosheets corresponding to layer 310 (e.g., Si). Further, as illustrated, the nanosheet stack structure 322 may include nanosheets 328 comprising three nanosheets corresponding to layer 308 (e.g., Ge or SiGe) and two nanosheets corresponding to layer 310 (e.g., Si). Additionally, as illustrated, the nanosheet stack structure 324 may include nanosheets 330 comprising two nanosheets corresponding to layer 308 (e.g., Ge or SiGe) and two nanosheets corresponding to layer 310 (e.g., Si).

Thereafter, as illustrated in FIG. 3G, the first photo-resist mask 312, the second photo-resist mask 314, and the third photo-resist mask 316 may then be removed from the nanosheet stack structures 320, 322, and 324.

Thereafter, as illustrated in FIG. 3H, nanosheets corresponding to layers 308 (e.g., the Ge or SiGe layers) in nanosheets 326 of the nanosheet stack structure 320 may be selectively removed (e.g., etched), leaving nanosheets corresponding to layers 310 (e.g., Si layers) in the nanosheets 326 of the nanosheet stack structure 320 intact. In some cases, the nanosheets corresponding to layers 308 (e.g., the Ge or SiGe layers) in nanosheets 326 of the nanosheet stack structure 320 may be removed (e.g., etched) using tetramethyl ammonium hydroxide (C₄H₁₃NO). Similarly, nanosheets corresponding to layers 308 (e.g., the Ge or SiGe layers) in nanosheets 328 of the nanosheet stack structure 322 may be selectively removed (e.g., etched), leaving nanosheets corresponding to layers 310 (e.g., Si layers) in the nanosheets 328 of the nanosheet stack structure 322 intact. Thus, as illustrated, after the nanosheets corresponding to layers 308 in nanosheets 326 and 328 are removed (e.g., etched), the nanosheets 326 of nanosheet stack structure 320 and nanosheets 328 of nanosheet stack structure 322 may comprise only nanosheets corresponding to layers 310 (e.g., only Si layers). As illustrated, the nanosheets corresponding to layers 310 in nanosheets 326 and nanosheets 328 may be separated by an air gap 332 from each other.

Thereafter, as illustrated in FIG. 31, nanosheets corresponding to layers 310 (e.g., the Si layers) in nanosheets 330 of the nanosheet stack structure 324 may be selectively removed (e.g., etched), leaving nanosheets corresponding to layers 308 (e.g., the Ge or SiGe layers) in the nanosheets 330 of the nanosheet stack structure 324 intact. In some cases, the nanosheets corresponding to layers 310 (e.g., the Si layers) in nanosheets 330 of the nanosheet stack structure 324 may be selectively removed (e.g., etched) using hydrofluoric acid, hydrogen peroxide, and acetic acid (HF:H₂O₂:CH₃COOH). Thus, as illustrated, after the nanosheets corresponding to layers 310 in nanosheets 330 are removed (e.g., etched), the nanosheets 330 of nanosheet stack structure 324 may comprise only nanosheets corresponding to layers 308. As illustrated, the nanosheets corresponding to layers 308 in nanosheets 330 may be separated by an air gap 334 from each other.

Further, as illustrated, due to the etching and placement of the photo-resist masks in FIGS. 3D-3E, the nanosheets corresponding to layers 308 in nanosheets 330 of nanosheet stack structure 324 may be offset and in different horizontal planes from the nanosheets corresponding to layers 310 in nanosheets 326 of nanosheet stack structure 320 and nanosheets 328 in nanosheet stack structure 322. Likewise, as illustrated the air gap 334 separating the nanosheets corresponding to layers 308 in nanosheets 330 may be offset and in a different horizontal plane from the air gap 332 separating the nanosheets corresponding to layers 310 in nanosheets 326 and nanosheets 328.

Thereafter, as illustrated in FIG. 3J, a high dielectric constant and metal gate (HKMG) structure 336 may be deposited above (e.g., on top of) the oxide layer 304, surrounding the nanosheets in nanosheets 326, 328, and 330 and filling in the air gaps 332 and 334 between the nanosheets in nanosheets 326, 328, and 330.

As illustrated, to improve performance and density of an electrical device, such as an SRAM, that employs the GAA semiconductor device 200, the number of nanosheets in nanosheets 326, 328, and 330 may be different from each other. For example, as illustrated, the nanosheets 326 of the nanosheet stack structure 320 may include three nanosheets, the nanosheets 328 of the nanosheet stack structure 322 may include two nanosheets, and the nanosheets 330 of the nanosheet stack structure 324 may include two nanosheets. It should be noted that the nanosheet stack structures 320, 322, and 324 may include any number of nanosheets and that the number of nanosheets in the nanosheet stack structures 320, 322, and 324 illustrated in FIGS. 3A-3J is not intended to be limiting. For example, in some cases, the nanosheets 326 of the nanosheet stack structure 320 may include four nanosheets, the nanosheets 328 of the nanosheet stack structure 322 may include three nanosheets, and the nanosheets 330 of the nanosheet stack structure 324 may include two nanosheets (e.g., as shown in FIG. 2).

Additionally, as described above, semiconductor materials of the nanosheets 326, 328, and 330 may be different from each other. For example, as illustrated, the semiconductor material of the nanosheets 326 and the nanosheets 328 may comprise silicon, whereas the nanosheets 330 may comprise a different semiconductor material, such as germanium or silicon germanium. Further, in some cases, while not illustrated, a width of the nanosheets 326, 328, and 330 may be independently varied, allowing for wider or narrower channels.

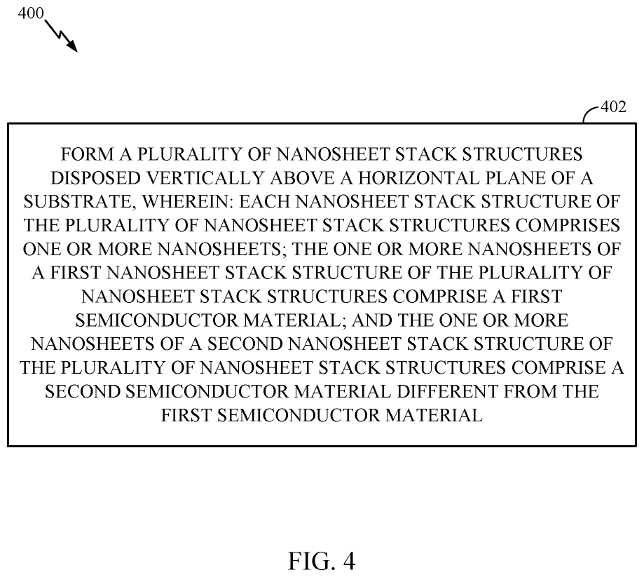

FIG. 4 is a flow diagram illustrating example operations 700 for fabricating a GAA semiconductor device, in accordance with certain aspects of the present disclosure. The operations 400 may be performed, for example, by a semiconductor processing facility.

The operations 400 begin, at block 402, with the semiconductor processing facility forming a plurality of nanosheet stack structures disposed vertically above a horizontal plane of a substrate. In some cases, each nanosheet stack structure of the plurality of nanosheet stack structures comprises one or more nanosheets. Additionally, in some cases, the one or more nanosheets of a first nanosheet stack structure of the plurality of nanosheet stack structures comprise a first semiconductor material.

Additionally, in some cases, the one or more nanosheets of a second nanosheet stack structure of the plurality of nanosheet stack structures comprise a second semiconductor material different from the first semiconductor material. For example, in some cases, the first semiconductor material comprises one of germanium (Ge) or silicon germanium (SiGe) and the second semiconductor material comprises silicon (Si).

In some cases, nanosheet stack structures of the GAA semiconductor device may be part of different transistor devices. For example, in some cases, the first nanosheet stack structure is part of a pull-up transistor. Additionally, in some cases, the second nanosheet stack structure is part of a pull-down transistor.

Further, in some cases, forming the plurality of nanosheet stack structures comprises forming the first nanosheet stack structure with a first number of nanosheets. Additionally, in some cases, forming the plurality of nanosheet stack structures comprises forming the second nanosheet stack structure with a second number of nanosheets different from the first number of nanosheets of the first nanosheet stack structure.

In some cases, the plurality of nanosheet stack structures of the GAA semiconductor device comprises a third nanosheet stack structure. According to aspects, the third nanosheet stack structure comprises a third number of nanosheets different from the first number of nanosheets of the first nanosheet stack structure and different from the second number of nanosheets of the second nanosheet stack structure. Thus, in some cases, forming the plurality of nanosheet stack structures comprises forming the third nanosheet stack structure with a third number of nanosheets. Additionally, in some cases, the one or more nanosheets of the third nanosheet stack structure comprise a third semiconductor material different from the first semiconductor material. For example, in some cases, the third semiconductor material comprises primarily silicon (Si). Additionally, in some cases, the third nanosheet stack structure is part of a pass-gate transistor.

According to aspects, in some cases, the one or more nanosheets of at least the first nanosheet stack structure are stacked vertically in relation to each other above the horizontal plane of the substrate of the GAA semiconductor device. Similarly, the one or more nanosheets of the second nanosheet stack structure (and/or the third nanosheet stack structure) are stacked vertically in relation to each other above the horizontal plane of the substrate of the GAA semiconductor device.

Additionally, in some cases, the one or more nanosheets of the first nanosheet stack structure are separated from each other by a high dielectric constant and metal gate structure. Similarly, the one or more nanosheets of the second nanosheet stack structure and the third nanosheet stack structure are separated from each other by the high dielectric constant and metal gate structure.

Additionally, in some cases, the first nanosheet stack structure and the second nanosheet stack structure extend orthogonally above the horizontal plane of the substrate.

Additionally, in some cases, a width of the one or more nanosheets of the first nanosheet stack structure is different from a width of the one or more nanosheets of the second nanosheet stack structure.

Additionally, in some cases, the first semiconductor material depends on a type of device to which the first nanosheet stack structure corresponds. Likewise, in some cases, the second semiconductor material depends on a type of device to which the second nanosheet stack structure corresponds. Likewise, in some cases, the third semiconductor material depends on a type of device to which the third nanosheet stack structure corresponds.

Additionally, in some cases, forming the plurality of nanosheet stack structures disposed vertically above the horizontal plane of the substrate comprises forming an oxide layer above (e.g., on top of) the substrate.

Additionally, in some cases, forming the plurality of nanosheet stack structures disposed vertically above the horizontal plane of the substrate comprises growing an epitaxial structure above (e.g., on top of) the oxide layer, wherein the epitaxial structure comprises alternating layers of differing materials. For example, in some cases, a first layer of the alternating layers may comprise a layer of silicon. Additionally, in some cases, a second layer of the alternating layers may comprise a layer of germanium or silicon germanium. According to aspects, the first layer and the second layer may be repeated throughout the epitaxial structure.

Further, in some cases, forming the plurality of nanosheet stack structures disposed vertically above the horizontal plane of the substrate comprises depositing a first photo-resist mask above (e.g., on top of) the epitaxial structure. In some cases, the first photo-resist layer may be deposited on a location of the epitaxial structure corresponding to the first nanosheet stack structure.

Further, in some cases, forming the plurality of nanosheet stack structures disposed vertically above the horizontal plane of the substrate comprises etching a first number of layers of the epitaxial structure, leaving a first number of remaining epitaxial layers.

Further, in some cases, forming the plurality of nanosheet stack structures disposed vertically above the horizontal plane of the substrate comprises depositing a second photo-resist mask above (e.g., on top of) the first number of remaining epitaxial layers. In some cases, the second photo-resist layer may be deposited on a location of the epitaxial structure (e.g., on the first number of remaining epitaxial layers) corresponding to the third nanosheet stack structure.

Further, in some cases, forming the plurality of nanosheet stack structures disposed vertically above the horizontal plane of the substrate comprises etching a second number of layers of the epitaxial structure, leaving a second number of remaining epitaxial layers.

Further, in some cases, forming the plurality of nanosheet stack structures disposed vertically above the horizontal plane of the substrate comprises depositing a third photo-resist mask above (e.g., on top of) the second number of remaining epitaxial layers. In some cases, the third photo-resist layer may be deposited on a location of the epitaxial structure (e.g., second number of remaining epitaxial layers) corresponding to the second nanosheet stack structure.

Further, in some cases, forming the plurality of nanosheet stack structures disposed vertically above the horizontal plane of the substrate comprises etching a third number of layers of the epitaxial structure, removing remaining epitaxial layers.

Further, in some cases, forming the plurality of nanosheet stack structures disposed vertically above the horizontal plane of the substrate comprises removing the first photo-resist mask, the second photo-resist mask, and the third photo-resist mask.

Further, in some cases, forming the plurality of nanosheet stack structures disposed vertically above the horizontal plane of the substrate comprises selectively removing (e.g., etching) the second layers corresponding to the first nanosheet stack structure and the third nanosheet stack structure, leaving one or more nanosheets corresponding to the first nanosheet stack structure and the third nanosheet stack structure. For example, as noted above, the second layers may comprise a semiconductor material such as germanium or silicon germanium. In some cases, removing the second layers may comprise using tetramethyl ammonium hydroxide (C₄H₁₃NO) to remove the first layers.

Further, in some cases, forming the plurality of nanosheet stack structures disposed vertically above the horizontal plane of the substrate comprises selectively removing (e.g., etching) the first layers corresponding to the second nanosheet stack structure, leaving one or more nanosheets corresponding to the second nanosheet stack structure. For example, as noted above, the first layers may comprise a semiconductor material such as silicon. In some cases, removing the first layers may comprise using hydrofluoric acid, hydrogen peroxide, and acetic acid (HF:H₂O₂:CH₃COOH) to remove the first layers.

Further, in some cases, forming the plurality of nanosheet stack structures disposed vertically above the horizontal plane of the substrate comprises depositing the high dielectric constant and metal gate structure above (e.g., on top of) the oxide layer and surrounding the one or more nanosheets corresponding to the first nanosheet stack structure, the second nanosheet stack structure, and the third nanosheet stack structure.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

What is claimed is:

1. A gate-all-around (GAA) semiconductor device comprising:
a plurality of nanosheet stack structures disposed vertically above a horizontal plane of a substrate, wherein:
each nanosheet stack structure of the plurality of nanosheet stack structures comprises one or more nanosheets;
the one or more nanosheets of a first nanosheet stack structure of the plurality of nanosheet stack structures comprise a first semiconductor material; and
the one or more nanosheets of a second nanosheet stack structure of the plurality of nanosheet stack structures comprise a second semiconductor material different from the first semiconductor material.

2. The GAA semiconductor device of claim 1, wherein:
the first semiconductor material comprises one of germanium (Ge) or silicon germanium (SiGe); and
the second semiconductor material comprises silicon (Si).

3. The GAA semiconductor device of claim 1, wherein:
the first nanosheet stack structure is part of a pull-up transistor; and
the second nanosheet stack structure is part of a pull-down transistor.

4. The GAA semiconductor device of claim 1, wherein:
the first nanosheet stack structure comprises a first number of nanosheets; and
the second nanosheet stack structure comprises a second number of nanosheets different than the first number of nanosheets of the first nanosheet stack structure.

5. The GAA semiconductor device of claim 4, wherein:
the plurality of nanosheet stack structures comprises a third nanosheet stack structure;
the third nanosheet stack structure comprises a third number of nanosheets different from the first number of nanosheets of the first nanosheet stack structure and different from the second number of nanosheets of the second nanosheet stack structure; and
the one or more nanosheets of the third nanosheet stack structure comprise a third semiconductor material different from the first semiconductor material.

6. The GAA semiconductor device of claim 5, wherein the third semiconductor material comprises primarily silicon (Si).

7. The GAA semiconductor device of claim 5, wherein the third nanosheet stack structure is part of a pass-gate transistor.

8. The GAA semiconductor device of claim 5, wherein:
the first semiconductor material depends on a type of device to which the first nanosheet stack structure corresponds;
the second semiconductor material depends on a type of device to which the second nanosheet stack structure corresponds; and
the third semiconductor material depends on a type of device to which the third nanosheet stack structure corresponds.

9. The GAA semiconductor device of claim 1, wherein the one or more nanosheets of at least the first nanosheet stack structure are stacked vertically in relation to each other above the horizontal plane of the substrate of the GAA semiconductor device.

10. The GAA semiconductor device of claim 9, wherein the one or more nanosheets of at least the first nanosheet stack structure are separated from each other by a high dielectric constant and metal gate structure.

11. The GAA semiconductor device of claim 1, wherein a width of the one or more nanosheets of the first nanosheet stack structure is different from a width of the one or more nanosheets of the second nanosheet stack structure.

12. A method for fabricating a gate-all-around semiconductor device, comprising:
forming a plurality of nanosheet stack structures disposed vertically above a horizontal plane of a substrate, wherein:
each nanosheet stack structure of the plurality of nanosheet stack structures comprises one or more nanosheets;
the one or more nanosheets of a first nanosheet stack structure of the plurality of nanosheet stack structures comprise a first semiconductor material; and
the one or more nanosheets of a second nanosheet stack structure of the plurality of nanosheet stack structures comprise a second semiconductor material different from the first semiconductor material.

13. The method of claim 12, wherein:
the first semiconductor material comprises one of germanium (Ge) or silicon germanium (SiGe); and
the second semiconductor material comprises silicon (Si).

14. The method of claim 12, wherein forming the plurality of nanosheet stack structures comprises growing an epitaxial structure above an oxide layer disposed above the substrate, wherein the epitaxial structure comprises a plurality of alternating epitaxial layers of differing materials.

15. The method of claim 14, wherein forming the plurality of nanosheet stack structures comprises:
forming the first nanosheet stack structure with a first number of nanosheets; and
forming the second nanosheet stack structure with a second number of nanosheets different than the first number of nanosheets of the first nanosheet stack structure.

16. The method of claim 15, wherein forming the plurality of nanosheet stack structures further comprises:
forming a third nanosheet stack structure comprising a third number of nanosheets different from the first number of nanosheets of the first nanosheet stack structure and different from the second number of nanosheets of the second nanosheet stack structure, wherein the one or more nanosheets of the third nanosheet stack structure comprise a third semiconductor material different from the first semiconductor material.

17. The method of claim 16, wherein the third semiconductor material comprises primarily silicon (Si).

18. The method of claim 16, wherein:
forming the first nanosheet stack structure comprises depositing a first photo-resist mask above the epitaxial structure on a location of the epitaxial structure corresponding to the first nanosheet stack structure and etching a first number of layers of the epitaxial structure, leaving a first number of remaining epitaxial layers;
forming the third nanosheet stack structure comprises depositing a second photo-resist mask above the first number of remaining epitaxial layers on a location of the first number of remaining epitaxial layers corresponding to the third nanosheet stack structure and etching a second number of layers of the epitaxial structure, leaving a second number of remaining epitaxial layers; and
forming the second nanosheet stack structure comprises depositing a third photo-resist mask above the second number of remaining epitaxial layers on a location of the second number of remaining epitaxial layers corresponding to the second nanosheet stack structure and etching a third number of layers of the epitaxial structure, removing remaining epitaxial layers.

19. The method of claim 12, wherein the one or more nanosheets of at least the first nanosheet stack structure are separated from each other by a high dielectric constant and metal gate structure.

20. The method of claim 12, wherein a width of the one or more nanosheets of the first nanosheet stack structure is different from a width of the one or more nanosheets of the second nanosheet stack structure.
